(19) United States
(12) Patent Application Publication
(10) Pub. No.: US 2026/0109243 A1
(43) Pub. Date: Apr. 23, 2026

(54) CHARGER AND METHOD OF MANUFACTURING THE SAME

(71) Applicant: KABUSHIKI KAISHA TOYOTA JIDOSHOKKI, Aichi (JP)

(72) Inventors: Motoe YASHIMA, Kariya-shi (JP); Satoshi ITO, Kariya-shi (JP)

(73) Assignee: KABUSHIKI KAISHA TOYOTA JIDOSHOKKI, Aichi (JP)

(21) Appl. No.: 19/357,642

(22) Filed: Oct. 14, 2025

(30) Foreign Application Priority Data
Oct. 21, 2024 (JP) 2024-184686

(51) Int. Cl. B60L 53/16; B60R 16/02; H01R 13/58; H05K 7/14

(52) U.S. Cl. CPC B60L 53/16; B60R 16/0207; H01R 13/5804; H05K 7/14322; B60L 2210/30

(57) ABSTRACT

A charger mounted on a vehicle includes a connector into which a cable connector of a cable through which a voltage is supplied from a charging equipment is inserted, a supply circuit a connector terminal electrically connected to the connector, a first busbar through which the voltage is supplied to the supply circuit, a housing having an opening, and a cover covering the opening. The cover forms an accommodating space by closing the opening. The accommodating space accommodates the supply circuit, the first busbar, and the connector terminal. The cover has a first surface facing the accommodating space, a second surface, and a through hole. The connector is fixed to the second surface. The first busbar and the connector terminal are fixed and connected to each other with a fixing member. The fixing member is disposed in the through hole as viewed in a normal direction to the second surface.

### CROSS-REFERENCE TO RELATED APPLICATION

This application claims priority to Japanese Patent Application No. 2024-184686 filed on October 21, 2024, the entire disclosure of which is incorporated herein by reference.

### BACKGROUND ART

The present disclosure relates to a charger and a method of manufacturing the charger.

There is a charger for charging a battery of a vehicle disclosed in International Patent Application Publication No. 2013-073491. The charger is mounted in a motor compartment (also referred to as an engine compartment) of this vehicle. The charger has a housing and an inverter or the like disposed in the housing. A connector is disposed in a side wall of the housing of this charger. Cables are connected to the connector.

As described above, the charger is mounted in the motor compartment of the vehicle. In addition to the charger, other components are also mounted in the motor compartment. Also, the connector is disposed in the side wall of the housing as described above. Thus, a designer may want to position the connector in a cover of the charger, taking into consideration presence of the other components. However, in the conventional charger, the configuration in which the connector is disposed in the cover has not been considered.

The present disclosure is made to solve the above-described problem, and an object of one aspect is to provide a charger in which a connector is disposed in a cover and a method of manufacturing the charger.

### SUMMARY

In accordance with an aspect of the present disclosure, there is provided a charger mounted on a vehicle, the charger including a connector into which a cable connector of a cable through which a voltage is supplied from a charging equipment outside the vehicle is inserted, a supply circuit that supplies, to a battery of the vehicle, a power supplied to the connector, a connector terminal electrically connected to the connector, a first busbar through which the voltage is supplied to the supply circuit, a housing having an opening, and a cover covering the opening. The cover forms an accommodating space together with the housing by closing the opening. The accommodating space accommodates the supply circuit, the first busbar, and the connector terminal. The cover has a first surface facing the accommodating space, a second surface on an opposite side of the first surface, and a through hole. The connector is fixed to the second surface. The first busbar and the connector terminal are fixed and connected to each other with a fixing member. The fixing member is disposed in the through hole as viewed in a normal direction to the second surface.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The disclosure, together with objects and advantages thereof, may best be understood by reference to the following description of the embodiments together with the accompanying drawings in which:

FIG. 1 is a view for explanation of a state in which a charger according to a present embodiment is mounted on a vehicle;

FIG. 2 is a perspective view of a charger according to a comparative example;

FIG. 3 is a perspective view of the charger according to the present embodiment;

FIG. 4 is a perspective view of the charger having a pair of harnesses according to the present embodiment ;

FIG. 5 is a view for explanation of components inside the charger according to the present embodiment;

FIG. 6 is a plan view of the charger according to the present embodiment;

FIGS. 7A and 7B are views each illustrating a main part of the charger in which a cable connector is attached to a first connector according to the present embodiment;

FIG. 8 is a block diagram inside the charger according to the present embodiment;

FIG. 9 is a flowchart showing a main process of a method of manufacturing the charger according to the present embodiment;

FIG. 10 is a view illustrating a connector device according to the present embodiment;

FIG. 11 is a view illustrating a base device according to the present embodiment; and

FIG. 12 is a view illustrating a case in which the connector device is attached to the base device according to the present embodiment.

### DETAILED DESCRIPTION OF THE EMBODIMENTS

The following will describe an embodiment according to the present disclosure in detail with reference to the drawings. Note that in the drawings, identical or substantially identical components have the same reference numerals and may not be reiterated.

### [Vehicle and charger]

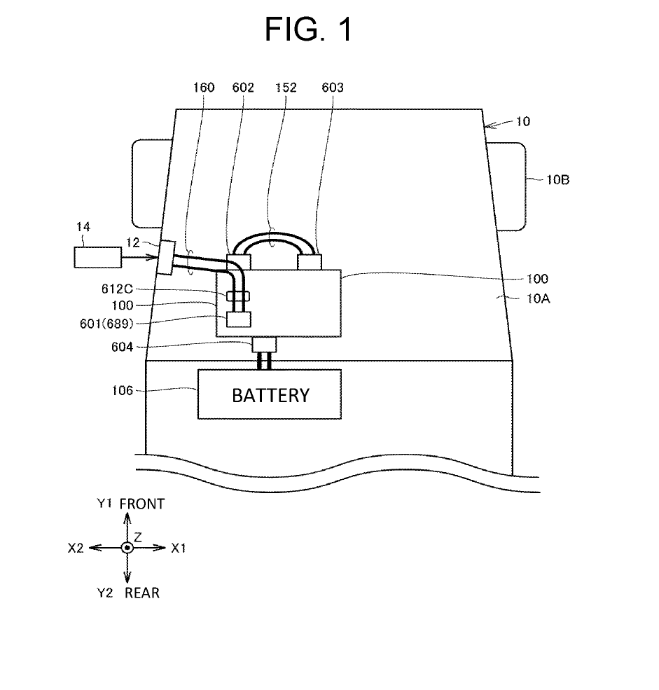

FIG. 1 is a view for explanation of a state in which a charger 100 according to the present embodiment is mounted on a vehicle 10. The vehicle 10 is an electric vehicle. The vehicle 10 mainly includes a charging port 12, a pair of cables 160, an engine compartment 10A, wheels 10B, a battery 106, and the like. Note that in a case where the vehicle 10 is an electric vehicle, there is no engine on the vehicle 10, but the engine compartment 10A is formally referred to as the engine compartment in the present embodiment. Furthermore, the charger 100 is mounted in the engine compartment 10A. The charger 100 is electrically connected to the pair of the cables 160, the battery 106, and the like.

In the present embodiment, a height direction of the vehicle 10 is defined as a Z-axis direction. The Z-axis direction is a direction of gravity applied to the charger 100 (hereinafter, also referred to as the "gravity direction"). A front-rear direction of the vehicle 10 is defined as a Y-axis direction. In particular, a front direction of the vehicle 10 is defined as a Y1-axis direction, and a rear direction of the vehicle 10 is defined as a Y2-axis direction. A left-right direction of the vehicle 10 is defined as an X-axis direction. In particular, a right direction of the vehicle 10 is defined as an X1-axis direction, and a left direction of the vehicle 10 is defined as an X2-axis direction. Furthermore, in a state where the charger 100 is mounted on the vehicle 10, the Z-axis direction is the same as a height direction of the charger 100.

In a case where the vehicle 10 is charged in a charging facility, or the like, for example, a station-side connector extending from a charging station 14 as a charging equipment outside the vehicle 10 is inserted into the charging port 12. An alternating current (AC) voltage and a direct current (DC) voltage are applied to the charging port 12 from the charging station 14.

A voltage from the charging station 14 is supplied to the charger 100 through the charging port 12 and the pair of the cables 160. The charger 100 includes a first connector 601, a second connector 602, a third connector 603, a fourth connector 604, and a pair of harnesses 152.

A cable connector 689 of the pair of the cables 160 through which the voltage is supplied from the charging station 14 is inserted into the first connector 601. The first connector 601 corresponds to the “connector” in the present disclosure. When a DC voltage is input to the first connector 601, the DC voltage is greater than 0 V and 1000 V or less. When an AC voltage is input to the first connector 601, the AC voltage is greater than 0 Vrms (Voltage Root-Mean-Square) and 293 Vrms or less.

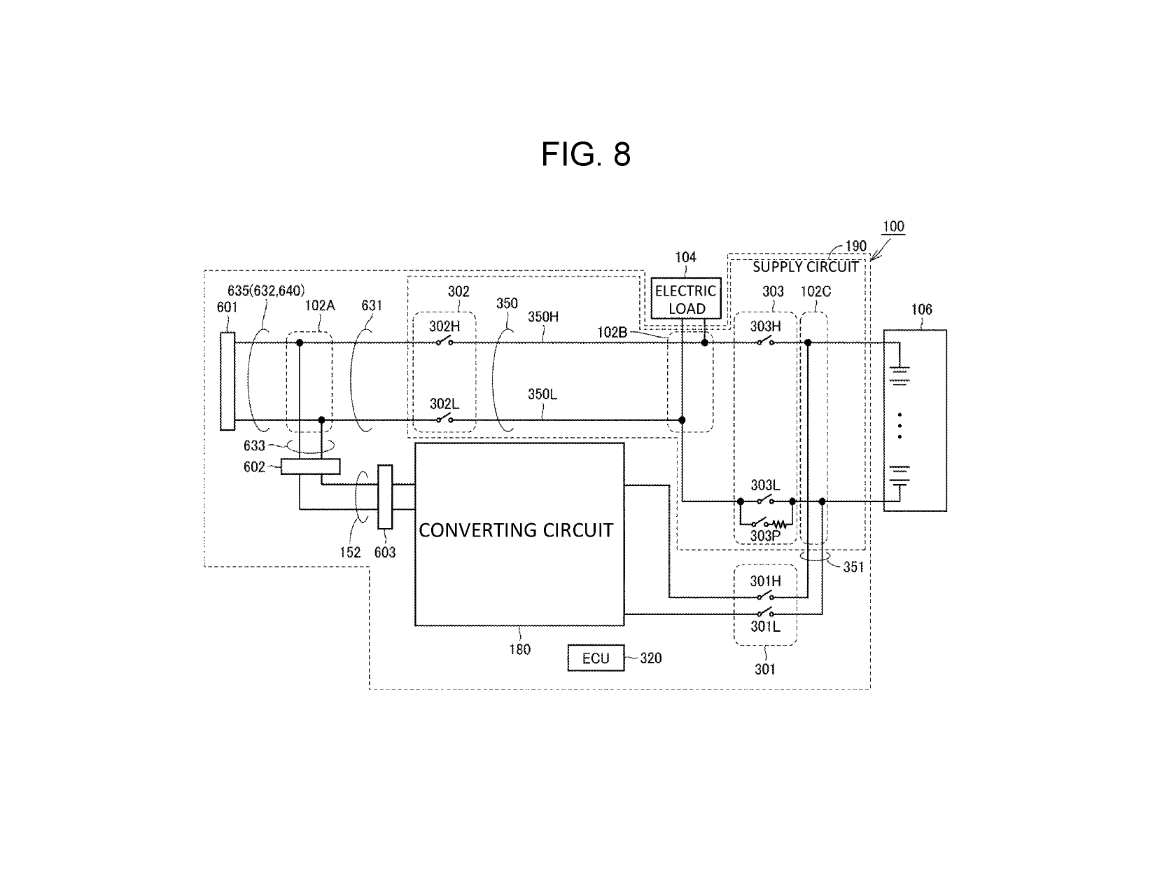

When the AC voltage is input to the first connector 601, the AC voltage is supplied to the second connector 602. The AC voltage is then input to the third connector 603 from the second connector 602 through the pair of the harnesses 152. The AC voltage is input to a converting circuit 180 (see FIG. 8) from the third connector 603.

The converting circuit 180 converts a voltage supplied to the first connector 601 and supplies the converted voltage to the battery 106. For example, when the AC voltage is supplied from the charging station 14, the converting circuit 180 converts the AC voltage to a DC voltage and supplies the DC voltage to the battery 106 through the fourth connector 604. The converting circuit 180 typically includes an on-board charger.

In addition, when the DC voltage is supplied from the charging station 14, the charger 100 supplies the DC voltage to the battery 106 through the fourth connector 604. Note that as a modification, the converting circuit 180 of the charger 100 may adjust a value of the DC voltage supplied from the charging station 14 and supply the adjusted DC voltage to the battery 106.

A pair of power lines in the present embodiment includes a high voltage wiring through which a high voltage current flows and a low voltage wiring through which a low voltage current flows. Similarly, the pair of the harnesses 152 includes a high voltage harness through which a high voltage current flows and a low voltage harness through which a low voltage current flows. Also, a busbar described below includes a pair of busbars that is a pair of a high voltage busbar and a low voltage busbar.

### [Charger in comparative example]

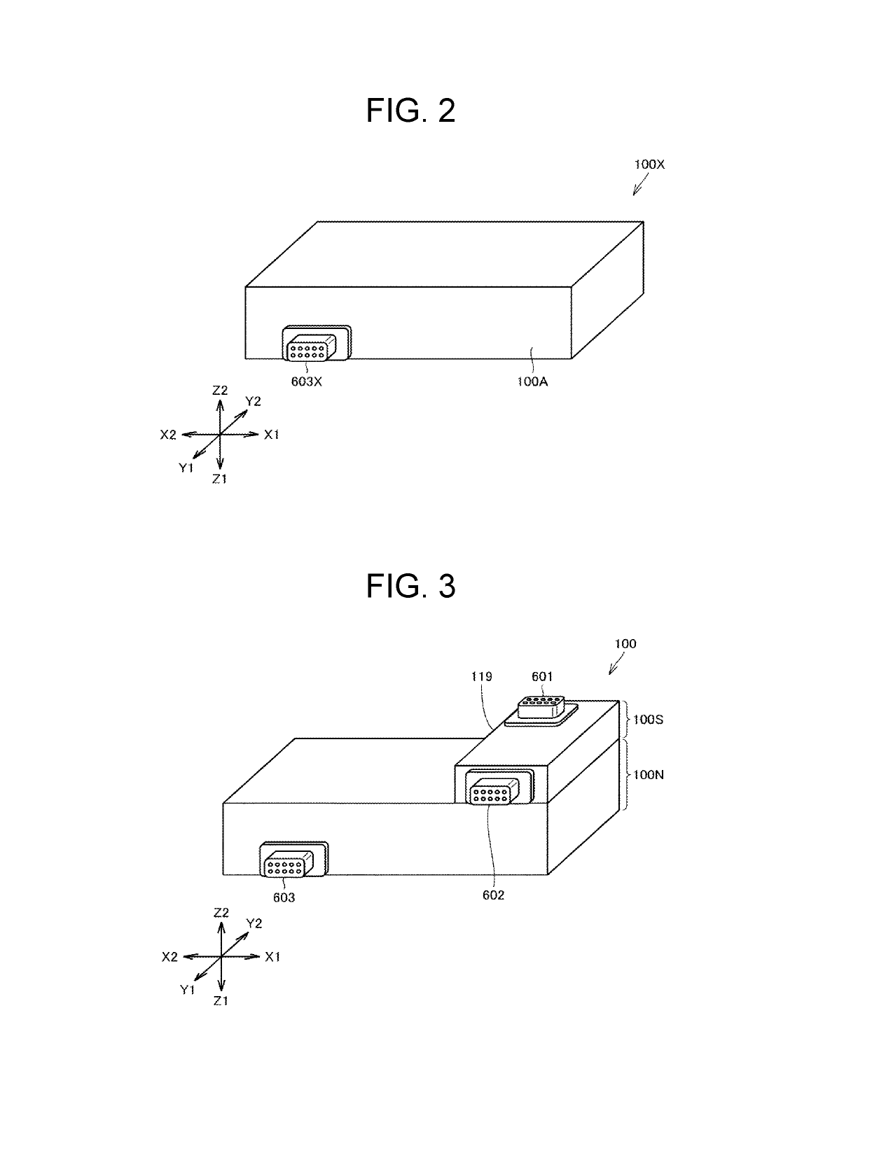

FIG. 2 is a perspective view of a charger 100X according to a comparative example. The charger 100X in the comparative example handles only AC charging without handling DC charging. In addition, a supply circuit, which will be described later, is not accommodated in the charger 100X. The charger 100X has a side surface 100A in which a connector 603X is disposed.

Here, the charger 100X is mounted in an engine compartment of a vehicle. In addition to the charger 100X, other components are also mounted in the engine compartment. In an example of FIG. 2, the connector 603X is disposed in the side surface 100A. When the connector 603X is disposed in the side surface 100A, a worker passes a wiring of the connector 603X from an outside of the charger 100X through a through hole, which is not illustrated, formed in the side surface 100A. Then, the worker fastens a flange portion of the connector 603X to the side surface 100A with screws, which are not illustrated. Thus, the worker inserts his/her hand into the charger 100X through an opening portion of the charger 100X and connects the wiring of the connector 603X to a component inside the charger 100X before closing a cover (upper surface) of the charger 100X.

Here, there may be a problem that it is troublesome to insert a cable into the connector 603X disposed in the side surface 100A because of presence of the other components, for example. The designer may want to position the connector in the cover (upper surface) of the charger 100X, taking into consideration the presence of such other components.

This leads to a configuration in which the connector 603X is disposed in the cover (upper surface) of the charger 100X. However, in the charger 100X of the comparative example, when the connector 603X is simply disposed in the cover (upper surface), after the connector 603X is fixed to the cover, a work of connecting the wiring of the connector 603X to a component inside the charger 100X is necessary before closing the cover of the charger 100X. For this reason, a long cable is needed as the wiring of the connector 603X and the worker needs to do the connecting work while holding the cover, which results in significant manufacturing costs.

The present embodiment provides the charger 100 in which manufacturing costs are suppressed by using the charger 100X in the comparative example and a connector is fixed to a cover.

### [Perspective view of charger in present embodiment]

FIG. 3 is a perspective view of the charger 100 according to the present embodiment. The charger 100 is a device including a base device 100N and a connector device 100S. An existing charger may be used as the base device 100N, and for example, the base device 100N may correspond to the charger 100X in the comparative example. The connector device 100S corresponds to the "cover unit" in the present disclosure. The base device 100N corresponds to the “housing unit” in the present disclosure.

As described above, the charger 100 has the first connector 601, the second connector 602, and the third connector 603. The first connector 601 and the second connector 602 are provided in the connector device 100S, and the third connector 603 is provided in the base device 100N.

Furthermore, in the connector device 100S, an area of a surface (a second surface 612B of a cover 611 described below) in which the first connector 601 is disposed is larger than that of a side surface of the connector device 100S.

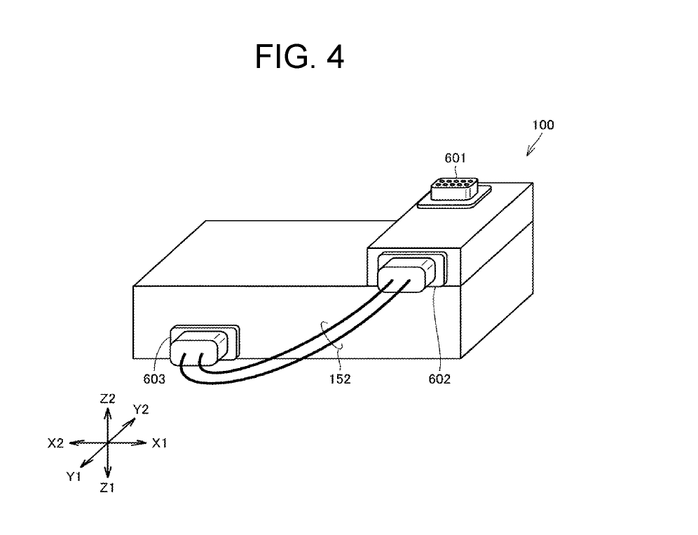

FIG. 4 is a perspective view of the charger 100 having the pair of the harnesses 152 according to the present embodiment. As described above, one end portions of the pair of the harnesses 152 are connected to the second connector 602, and the other end portions of the pair of the harnesses 152 are connected to the third connector 603.

### [Components inside the charger]

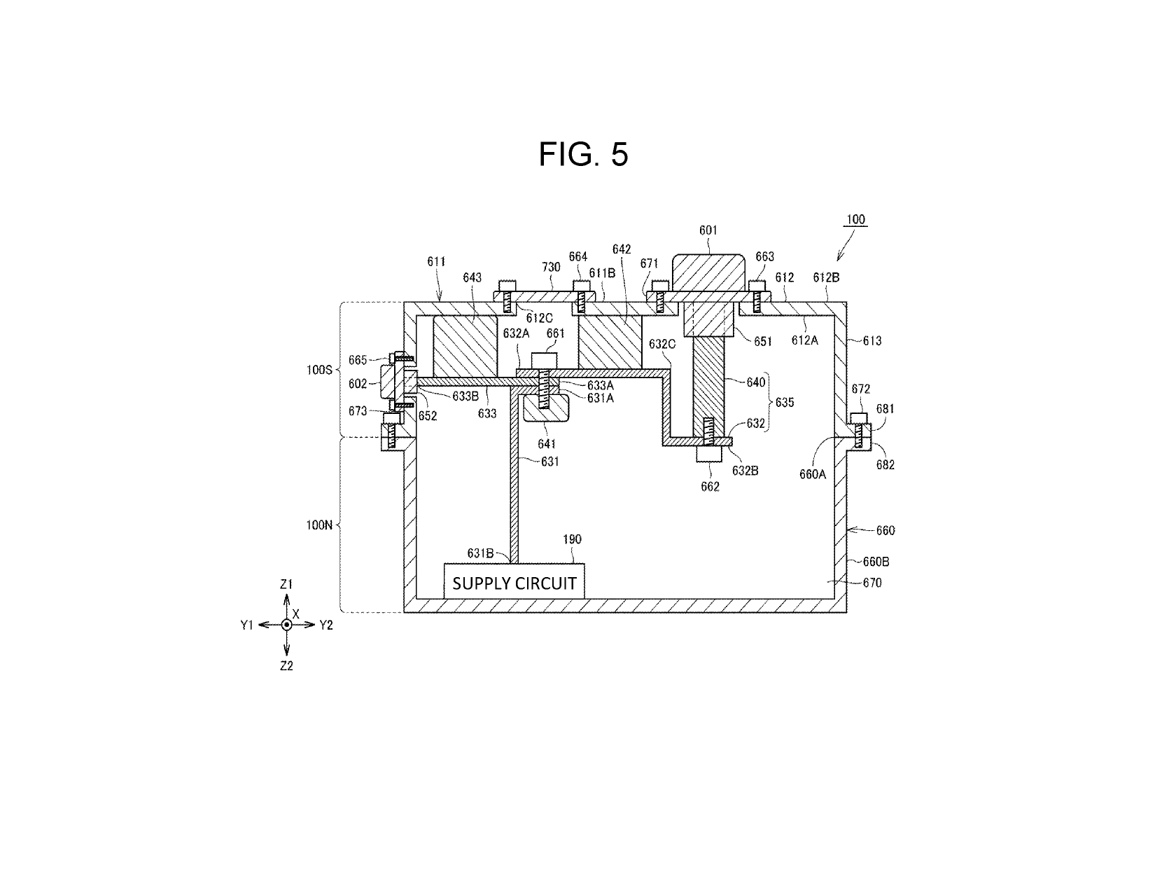

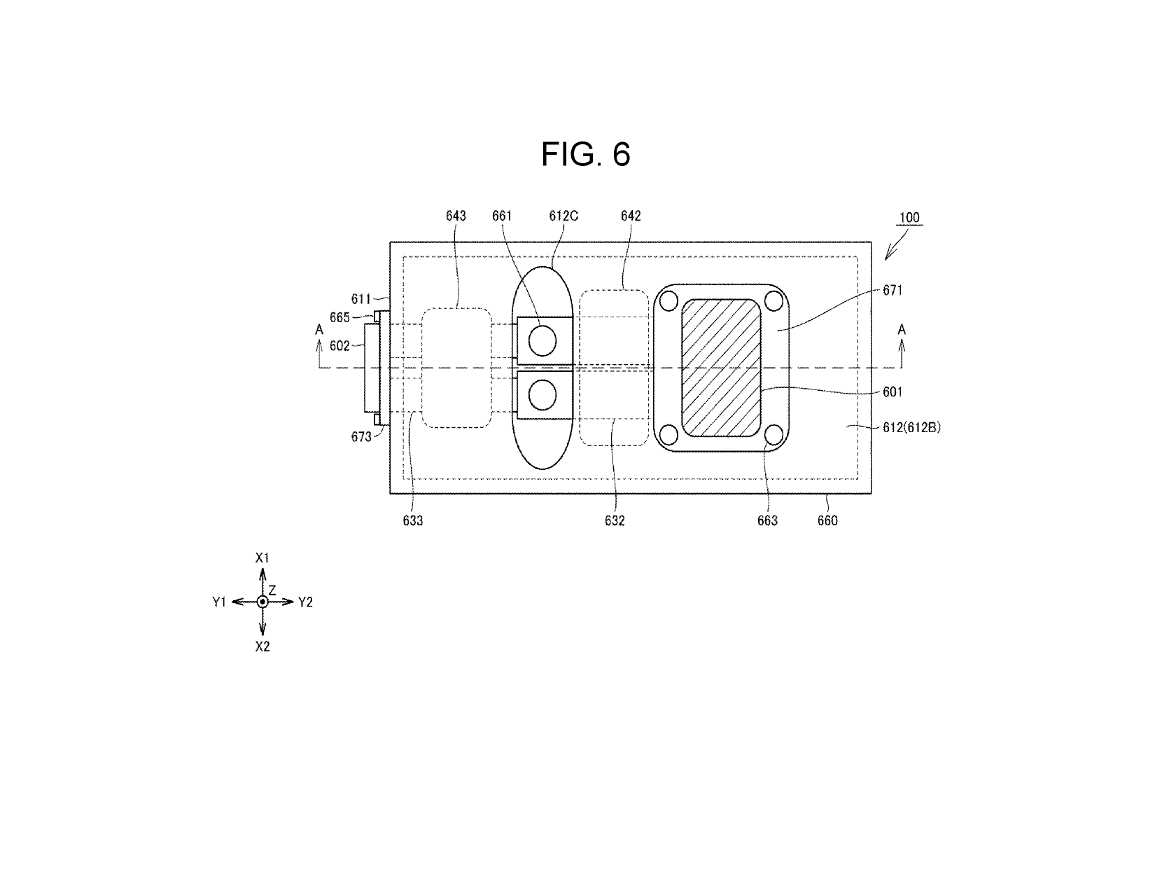

FIG. 5 is a view for explanation of components inside a main part of the charger 100 according to the present embodiment. FIG. 6 is a plan view of the connector device 100S of the charger 100. FIG. 5 is a schematic cross-sectional view taken along a line A-A in FIG. 6 and illustrates only one of the pair of the busbars.

As illustrated in FIG. 5, the charger 100 includes the cover 611 and a housing 660. An outer wall of the connector device 100S serves as the cover 611, and an outer wall of the base device 100N serves as the housing 660. The cover 611 has a top plate portion 612, a side wall 613, and a flange 681 formed on the side wall 613.

The top plate portion 612 has a first surface 612A, the second surface 612B, and a through hole 612C. The first surface 612A faces the second surface 612B across the top plate portion 612. The first surface 612A is a surface facing an accommodating space 670, which will be described later. The second surface 612B is a surface on an opposite side of the first surface 612A.

The housing 660 has an opening 660A and a side wall 660B. The housing 660 also has a flange 682 formed on the side wall 660B. The cover 611 is positioned on the housing 660 so that the cover 611 covers the opening 660A, and then, the flange 681 and the flange 682 are fixed to each other with fixing members 672. The fixing members in the present embodiment each are a screw. Note that any other member may be used as the fixing members as long as one component and the other component are fixed to each other with it.

The cover 611 is fixed to the housing 660 with the fixing members 672 and closes the opening 660A, which forms the accommodating space 670. A supply circuit 190, a first busbar 631, a third busbar 633, a connector terminal 635, a connector frame 651, and the like are accommodated in the accommodating space 670. The first busbar 631 corresponds to the "busbar" in the present disclosure.

The first connector 601 is fixed to the second surface 612B of the top plate portion 612. In addition, the first connector 601, the connector frame 651, and a flange 671 are integrally formed with each other. The connector frame 651 insulates a connecting portion between a connector terminal main body 640 and the first connector 601 from an outside of the connector frame 651. In an example of FIG. 5, the flange 671 is fixed to the cover 611 with fixing members 663, so that the first connector 601 is fixed to the second surface 612B.

The second connector 602 is fixed to the side wall 613. In addition, the second connector 602, a connector frame 652, and a flange 673 are integrally formed with each other. The connector frame 652 insulates a connecting portion between the third busbar 633 and the second connector 602 from an outside of the connector frame 652. In the example of FIG. 5, the flange 673 is fixed to the side wall 613 with fixing members 665, so that the second connector 602 is fixed to the side wall 613.

The connector terminal 635 includes the connector terminal main body 640 and a second busbar 632. The connector terminal main body 640 is formed so as to extend. In FIG. 6, the connector terminal main body 640 extends in the Z-axis direction. The connector terminal main body 640 is electrically connected to the first connector 601.

The second busbar 632 is formed so as to extend. The second busbar 632 has one end portion 632A and the other end portion 632B in a direction in which the second busbar 632 extends. The other end portion 632B and the connector terminal main body 640 are fixed and connected to each other with fixing members 662. In the example of FIG. 5, the fixing members 662 are fixed in the Z-axis direction. Furthermore, in the example of FIG. 5, the second busbar 632 has a curved portion 632C.

The first busbar 631 is formed so as to extend. The first busbar 631 has one end portion 631A and the other end portion 631B in a direction in which the first busbar 631 extends.

The third busbar 633 is formed so as to extend. The third busbar 633 has one end portion 633A and the other end portion 633B in a direction in which the third busbar 633 extends.

In addition, the first busbar 631, the second busbar 632, and the third busbar 633 are fixed to a first terminal base 641, a second terminal base 642, a third terminal base 643, respectively.

The first terminal base 641 is fixed to a predetermined component, which is not illustrated, of the housing 660 (base device 100N). Furthermore, the second terminal base 642 and the third terminal base 643 are fixed to a predetermined component (first surface 612A of the top plate portion 612 in an example of FIG. 6) of the connector device 100S.

The one end portion 631A of the first busbar 631, the one end portion 632A of the second busbar 632, and the one end portion 633A of the third busbar 633 are fixed and connected to each other with fixing members 661. The wording of "fixed and connected" means that one component and the other component are fixed and electrically connected to each other.

The other end portion 631B of the first busbar 631 is connected to the supply circuit 190. The other end portion 633B of the third busbar 633 is connected to the second connector 602. As described above, the power input from the second connector 602 is supplied to the converting circuit 180 through the pair of the harnesses 152. Accordingly, the third busbar 633 is a busbar through which a voltage is supplied to the converting circuit 180.

Furthermore, the charger 100 includes a closing member 730 for closing the through hole 612C. The closing member 730 is fixed to the cover 611 with fixing members 664.

FIG. 6 is a view of the connector device 100S of the charger 100 as viewed in a normal direction (Z-axis direction) to the second surface 612B of the cover 611. In other words, FIG. 6 is a view of the charger 100 as viewed in the gravity direction of the charger 100. The wording of "viewed in the normal direction" is also referred to as "viewed in a plan view". Note that the closing member 730, the fixing members 664, the flange 681, and the fixing members 672 are not illustrated in FIG. 6.

In FIG. 6, portions exposed on the outside of the charger 100 are illustrated by solid lines, and portions hidden behind the cover 611 are illustrated by broken lines. As illustrated in FIG. 6, the fixing members 661 are disposed in the through hole 612C as viewed in the normal direction to the second surface 612B. In other words, the fixing members 661 are located inside the through hole 612C as viewed in the normal direction to the second surface 612B.

Note that the cover 611 in FIG. 6 is a cover of the connector device 100S. The accommodating space 670 of the connector device 100S may communicate with an accommodating space of the base device 100N. In addition, the accommodating space 670 of the connector device 100S and the accommodating space of the base device 100N may be separately provided. That is, a partition may be provided between the accommodating space 670 of the connector device 100S and the accommodating space of the base device 100N.

The cover 611 may be formed integrally with a cover of the base device 100N, and the cover 611 and the cover of the base device 100N may be separately provided.

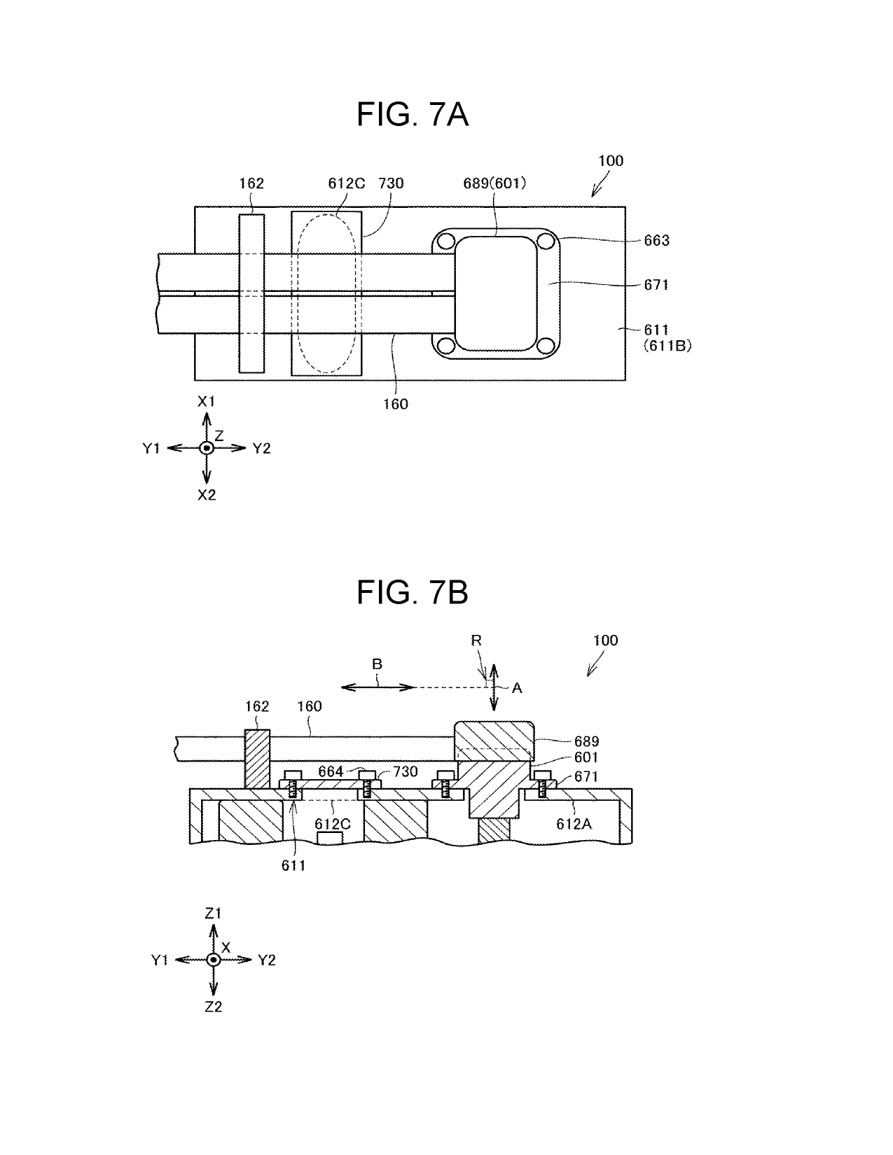

FIGS. 7A and 7B are views each illustrating a main part of the charger 100 to which the cable connector 689 of the cables 160 (see FIG. 1) is attached to (inserted into) the first connector 601. FIG. 7A is a plan view of the charger 100 in this case, and FIG. 7B is a view corresponding to FIG. 5 and illustrating a main part of the charger 100 in this case. Although the second connector 602, the flange 673, and the fixing members 665 are illustrated in FIG. 6, they are not illustrated in FIG. 7A. In addition, in FIG. 7A, although the closing member 730 attached to the cover 611 is illustrated, the fixing members 664 are not illustrated.

As illustrated in FIG. 7B, an inserting direction in which the cable connector 689 is inserted into the first connector 601 is the same as the above-described normal direction (Z-axis direction). The inserting direction is indicated by an arrow A in an example of FIG. 7B. In addition, in the state (see FIG. 1) in which the charger 100 is mounted on the vehicle 10, this normal direction is the height direction (Z-axis direction) of the vehicle 10.

In the example of FIG. 7B, a direction (extending direction) in which the cables 160 extend is the Y-axis direction. In the example of FIG. 7B, the extending direction of the cables 160 is indicated by an arrow B. As illustrated by the arrows A and B, the inserting direction in which the cable connector 689 is inserted into the first connector 601 is different from the extending direction of the cables 160. More specifically, an angle between the inserting direction (arrow A) and the extending direction (arrow B) is 90 degrees, as illustrated at a point R.

In addition, as illustrated in FIG. 7A, when the charger 100 is viewed in the normal direction, the cables 160 overlap at least a part of the through hole 612C. In other words, the cables 160 may overlap the whole through hole 612C. In addition, the cables 160 may overlap a part of the through hole 612C.

As illustrated in FIG. 7B, the pair of the cables 160 is fixed with a fixing base 162 (clamp). More specifically, the pair of the cables 160, at middle portions thereof between one ends and the other ends thereof, is fixed with the fixing base 162.

### [Circuit configuration of charger]

FIG. 8 is a block diagram inside the charger 100. FIG. 8 illustrates the first connector 601, the second connector 602, the third connector 603, the first busbar 631, the connector terminal 635 (the connector terminal main body 640 and the second busbar 632), the third busbar 633, and the pair of the harnesses 152. The charger 100 also includes first nodes 102A, a first power switching assembly 301, an electronic control unit (ECU) 320, the converting circuit 180, and the supply circuit 190. In addition, the vehicle 10 includes the battery 106 (see FIG. 1) and an electric load 104. In FIG. 8, the fourth connector 604 is not illustrated.

The first nodes 102A correspond to a portion at which the first busbar 631, the second busbar 632, and the third busbar 633 are fixed with the fixing members 661 (see FIG. 5), that is, the portion at which the first busbar 631, the second busbar 632, and the third busbar 633 are electrically connected to each other.

The first busbar 631 is a busbar extending from the first nodes 102A to the supply circuit 190. That is, the first busbar 631 is a busbar through which a voltage is supplied to the supply circuit 190. The connector terminal 635 (second busbar 632) is a busbar extending from the first connector 601 to the first nodes 102A. The third busbar 633 is a busbar extending from the first nodes 102A to the second connector 602.

The ECU 320 may identify whether the voltage input to the first connector 601 from the charging station 14 is the AC voltage or the DC voltage. For example, the charging station 14 sends a voltage type signal indicating that the voltage input to the first connector 601 is the AC voltage or the DC voltage to the ECU 320. The ECU 320 identifies whether the AC voltage or the DC voltage is to be supplied based on this voltage type signal.

The supply circuit 190 has a pair of power lines 350, second nodes 102B, third nodes 102C, a second power switching assembly 302, and a third power switching assembly 303. The supply circuit 190 supplies, to the battery 106 of the vehicle 10, the power supplied to the first connector 601. The pair of the power lines 350 is a pair of a high voltage power line 350H through which a high voltage current flows and a low voltage power line 350L through which a low voltage current flows. One ends of the pair of the power lines 350 in the supply circuit 190 are connected to the other end portion 631B of the first busbar 631 (see FIG. 5). That is, the first connector 601 and the battery 106 are electrically connected through the connector terminal 635, the first busbar 631, and the pair of the power lines 350.

The second nodes 102B are interposed between the first nodes 102A and the battery 106. The third nodes 102C are interposed between the second nodes 102B and the battery 106.

Power lines branch off from the pair of the power lines 350 at the second nodes 102B. The branching power lines are connected to the electric load 104. The electric load 104 is a load that generates driving power for the vehicle 10 by a power from the battery 106. The electric load 104 is, for example, a traction inverter.

Power lines branch off from the pair of the power lines 350 at the third nodes 102C. The branching power lines 351 are connected to an output side of the converting circuit 180.

One power switching assembly includes a high voltage relay that is provided on the high voltage power line and a low voltage relay that is provided on the low voltage power line. For example, the first power switching assembly 301 includes a high voltage relay 301H and a low voltage relay 301L. The first power switching assembly 301 is provided between the pair of the power lines 350 and the output side of the converting circuit 180. The second power switching assembly 302 is provided between the first nodes 102A and the second nodes 102B. The third power switching assembly 303 is provided between the second nodes 102B and the third nodes 102C.

In the present disclosure, “set the power switching assembly in an open state” means “set both the high voltage relay and the low voltage relay in the power switching assembly in an open state”. When the power switching assembly is set in the open state, a current cannot flow through the power switching assembly. On the other hand, “set the power switching assembly in a closed state” means “set both the high voltage relay and the low voltage relay in the power switching assembly in a closed state”. When the power switching assembly is set in the closed state, a current can flow through the power switching assembly.

Note that the third power switching assembly 303 includes a relay 303H, a relay 303L, and a relay 303P connected in series to a resistor. For example, when a capacitor of the electric load 104 is pre-charged at a startup of the vehicle 10, the charger 100 sets the relay 303H and the relay 303P in the closed state. This reduces the current due to the resistor connected to the relay 303P, so that it is suppressed that an inrush current flows into the capacitor of the electric load 104.

The ECU 320 performs control of charging from an external power supply and control of the open/closed states of a plurality of the power switching assemblies. The ECU 320 is also referred to as the “control circuit”.

### [Control of ECU 320]

Next, the control of the ECU 320 will be described. As described above, the ECU 320 performs the control of the open/closed states of the plurality of the power switching assemblies, and the like. This sets the vehicle 10 (charger 100) in any of a plurality of states. The plurality of the states includes a battery discharging state, an AC charging state, and a DC charging state.

First, the battery discharging state will be described. The battery discharging state is a state in which the battery 106 is discharged, for example, a state in which the vehicle 10 is driven (travels). The ECU 320 sets the first power switching assembly 301 in the closed state, sets the second power switching assembly 302 in the open state, and sets the third power switching assembly 303 in the closed state, thereby setting the charger 100 in the battery discharging state.

In the battery discharging state, the power from the battery 106 is supplied to the electric load 104.

Next, the AC charging state will be described. The AC charging state is a state in which the battery 106 is charged by the AC voltage supplied from the first connector 601. When the ECU 320 identifies that the AC voltage is supplied from the charging station 14, the ECU 320 sets the second power switching assembly 302 in the open state and sets the first power switching assembly 301 and the third power switching assembly 303 in the closed states.

Note that either the second power switching assembly 302 or the third power switching assembly 303 only needs to be set in the open state. Furthermore, when both the second power switching assembly 302 and the third power switching assembly 303 are set in the open state, it is suppressed that power is inadvertently supplied to the electric load 104.

In the AC charging state, the AC power supplied from the first connector 601 is input to the converting circuit 180 through the second connector 602 and the third connector 603. The converting circuit 180 converts the AC power to the DC power and supplies the DC power to the battery 106.

Next, the DC charging state will be described. When DC charging is performed, the ECU 320 sets the first power switching assembly 301 in the open state, and sets the second power switching assembly 302 and the third power switching assembly 303 in the closed states. This supplies the DC power supplied from the first connector 601 to the battery 106.

As described above, the ECU 320 sets the second power switching assembly 302 (switching circuit) in the open state for the AC charging state, whereas the ECU 320 sets the second power switching assembly 302 in the closed state for the DC charging state. In the charger 100 of the present embodiment, the battery 106 may be charged by such control, even when any of the AC power and the DC power is input to the first connector 601.

### [Manufacturing method]

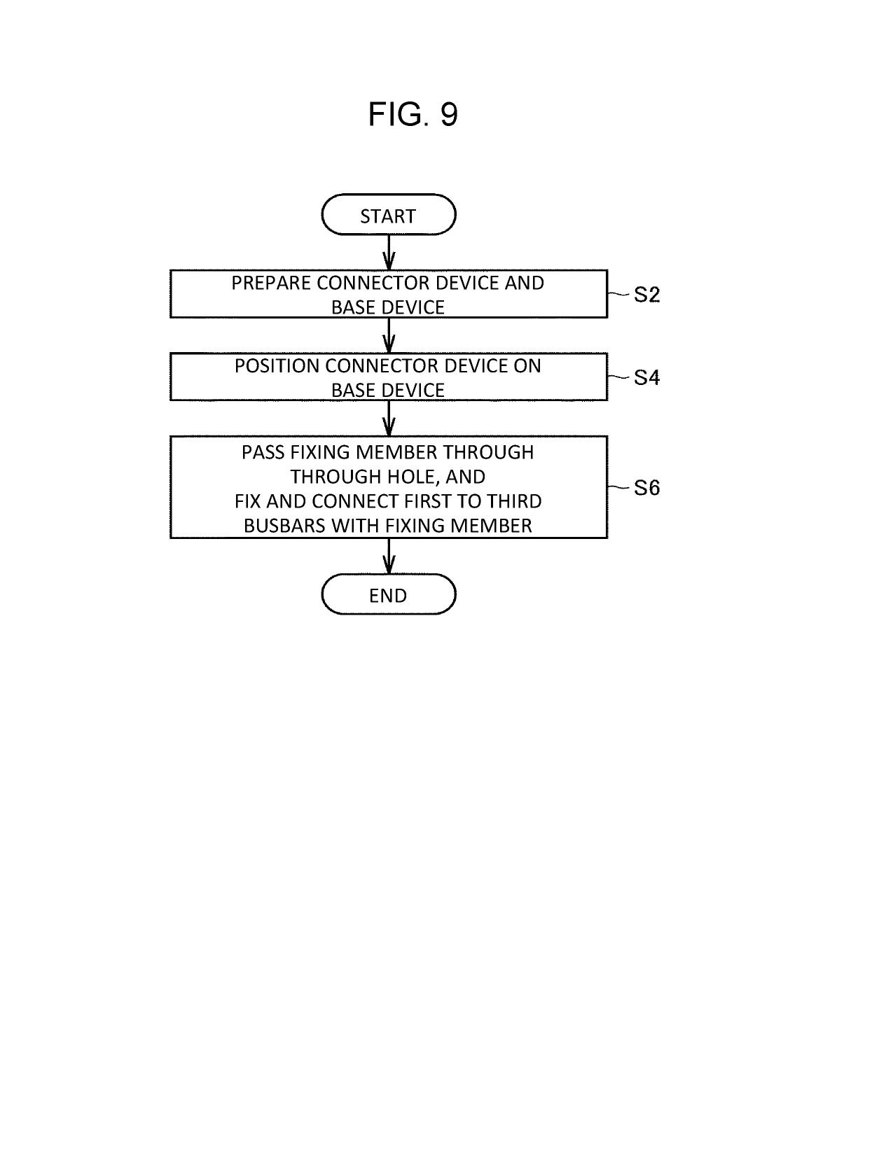

The following will describe a main process of a method of manufacturing the charger 100. FIG. 9 is a flowchart showing the main process of the method of manufacturing the charger 100. In addition, this process is carried out by at least one of a manufacturer (human) and a robot. The at least one of the manufacturer and the robot is also referred to as the “manufacturer or the like”.

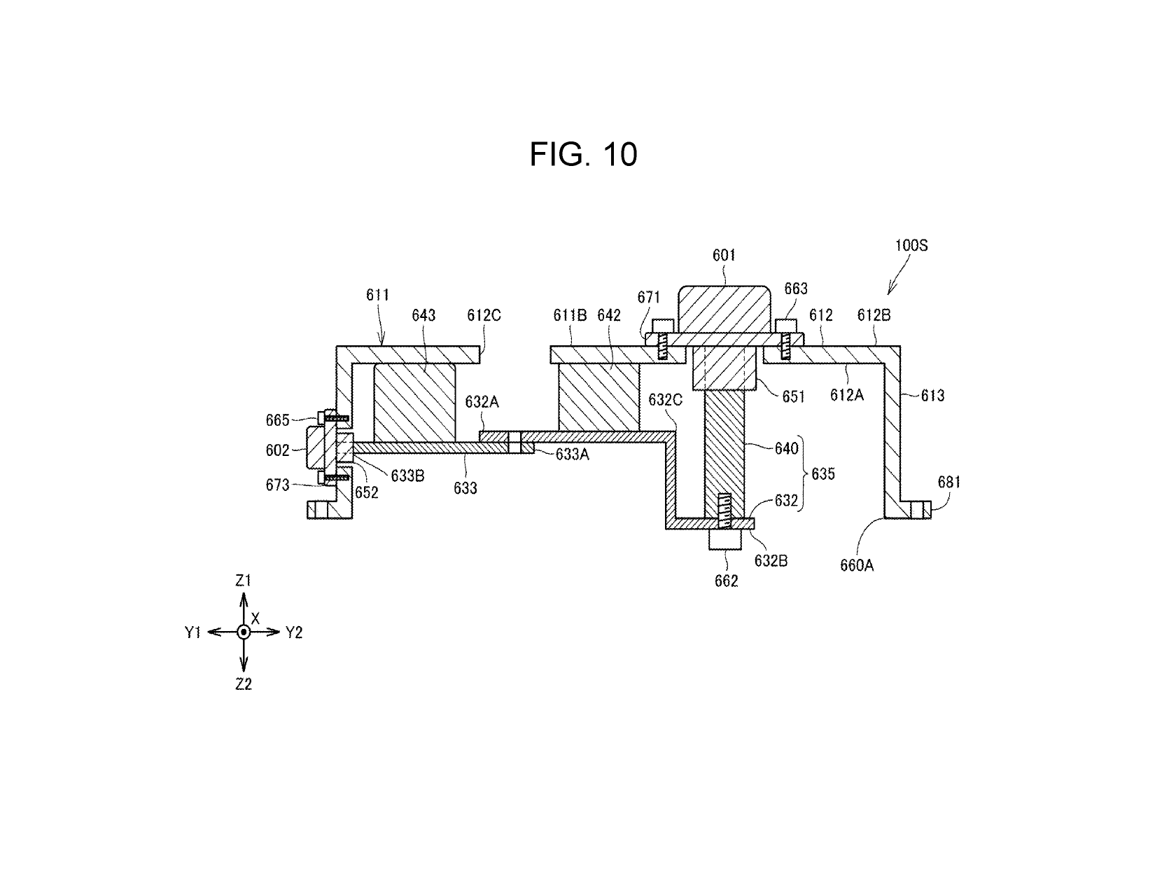

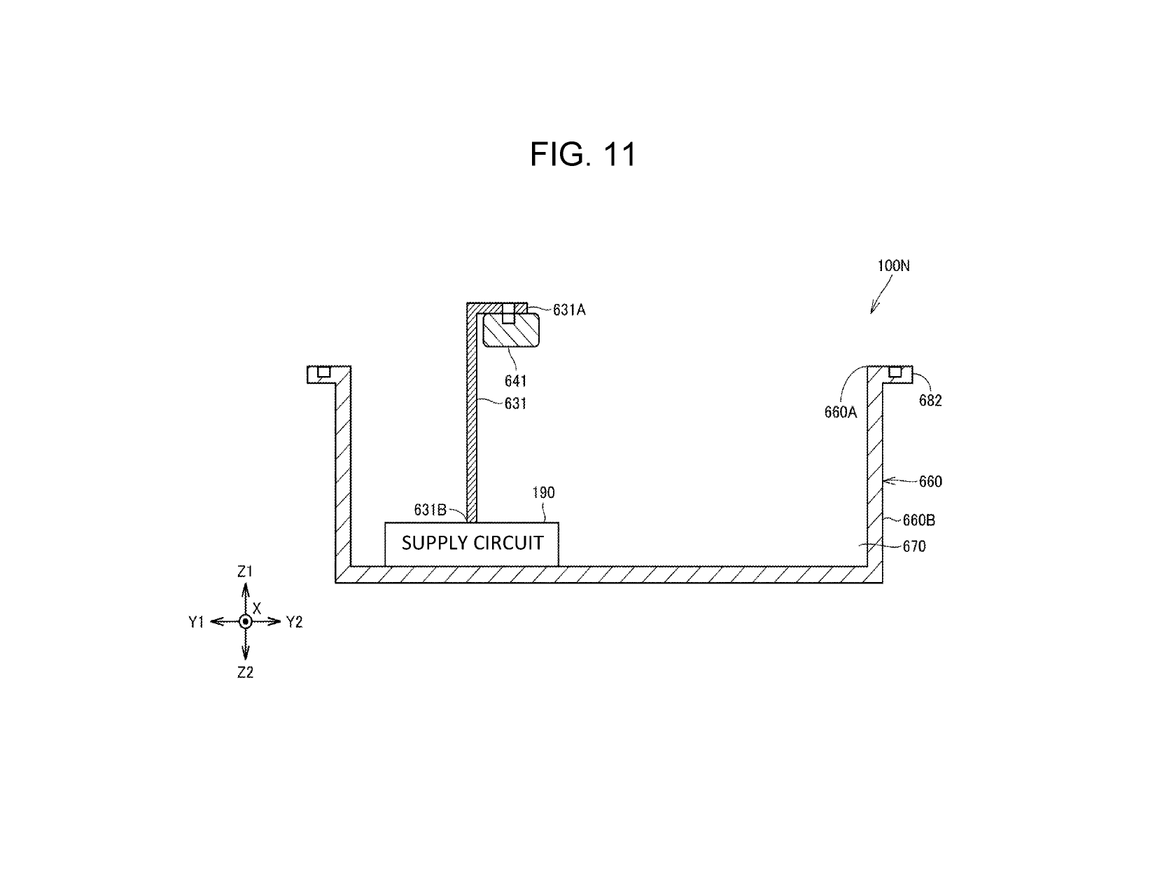

First, at Step S2, the connector device 100S (FIG. 10 described below) and the base device 100N (FIG. 11 described below) are prepared by the manufacturer or the like. Next, at Step S4, the connector device 100S is positioned on the base device 100N by the manufacturer or the like. After that, at Step S6, the manufacturer or the like passes the fixing members 661 through the through hole 612C to fix and connect the one end portion 631A of the first busbar 631, the one end portion 632A of the second busbar 632, and the one end portion 633A of the third busbar 633 to each other with the fixing members 661.

FIG. 10 is a view corresponding to the cross-section taken along the line A-A in FIG. 6 and illustrating the connector device 100S. FIG. 11 is a view corresponding to the cross-section taken along the line A-A in FIG. 6 and illustrating the base device 100N.

The connector device 100S in FIG. 10 mainly has the cover 611, the first connector 601, the second connector 602, the third busbar 633, the connector terminal 635, and the connector frame 651. As described using FIG. 5, the cover 611 has the first surface 612A, the second surface 612B, and the through hole 612C. The first connector 601 is fixed to the second surface 612B. The second busbar 632 and the third busbar 633 are fixed to the second terminal base 642 and the third terminal base 643, respectively. The second terminal base 642 and the third terminal base 643 are fixed to the cover 611. The second busbar 632 has through holes located near the one end portion 632A, and the third busbar 633 has through holes located near the one end portion 633A.

The base device 100N in FIG. 11 includes the housing 660, the supply circuit 190, the first busbar 631, and the first terminal base 641. The housing 660 has the opening 660A and the side wall 660B.

The first busbar 631 is fixed to the first terminal base 641. The first busbar 631 has through holes located near the one end portion 633A. Furthermore, the first terminal base 641 has engagement holes with which tips of the fixing members 661 are engaged.

Note that any process may be carried out as the manufacturing process of the connector device 100S and the manufacturing process of the base device 100N. Furthermore, the third connector 603 and the fourth connector 604 are fixed to the base device 100N in advance.

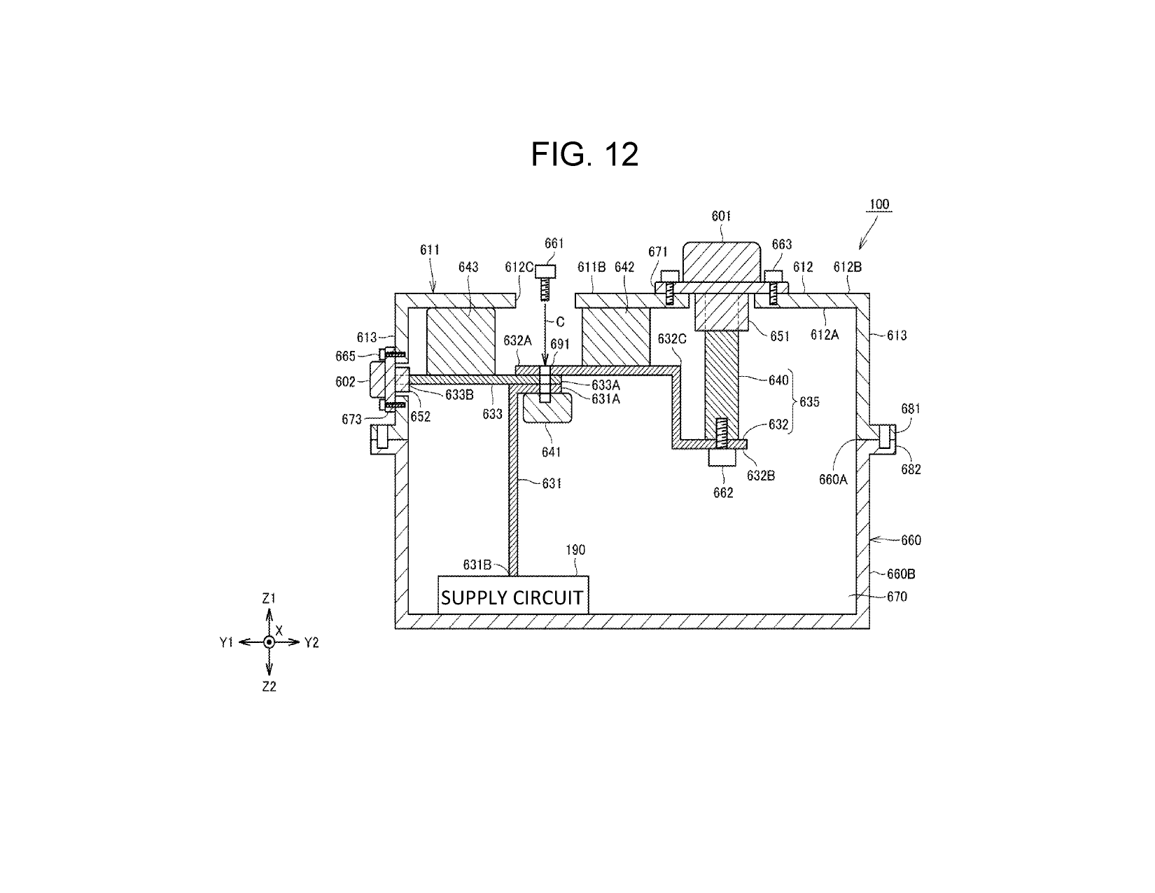

FIG. 12 is a view for explanation of Step S4 and Step S6 in FIG. 9. As illustrated in FIG. 12, at Step S4, the connector device 100S is positioned on the base device 100N so that the first surface 612A of the cover 611 faces the accommodating space 670 and the cover 611 covers the opening 660A. In addition, in an example of FIG. 12, the through holes of the first busbar 631, the through holes of the second busbar 632, the through holes of the third busbar 633, and the engagement holes of the first terminal base 641 form engagement holes 691 with which the fixing members 661 are engaged.

In step S6, the fixing members 661 are inserted through the through hole 612C and engaged with the engagement holes 691, as indicated by an arrow C in FIG. 12. The first busbar 631, the second busbar 632, and the third busbar 633 are fixed and connected to each other by engaging the fixing members 661 with the engagement holes 691. After that, the fixing with the fixing members 672 and the closing by the closing member 730 are performed.

(1) Generally, a charger is mounted in an engine compartment of a vehicle. In addition to the charger, other components are also mounted in the engine compartment. As illustrated in FIG. 2, the connector 603X of the charger 100X in the comparative example is disposed in the side surface 100A of the charger 100X. Accordingly, there may be a problem that it is troublesome to insert a cable into the connector because of presence of the other components in the engine compartment. A designer may want to position the connector in a cover of the charger, taking into consideration the presence of such other components.

However, the manufacturing of the charger in which the connector is disposed in the cover has not been conventionally considered. In contrast, in the charger 100 of the present embodiment, as illustrated in FIG. 5, the fixing members 661 are disposed inside the through hole 612C as viewed in the normal direction to the second surface 612B of the cover 611. Thus, the charger 100 in which the first connector 601 is disposed in the second surface 612B of the cover 611 is, for example, manufactured by the process described in FIGS. 9 to 12. More specifically, the charger 100 has the configuration in which the worker can connect wirings of the connectors to the components inside the charger 100 with the fixing members 661 after closing the cover 611. In the charger 100, there is no need to connect the wirings to the components inside the charger 100 before closing the cover 611, so that a long cable is not needed as the wiring and the charger 100 is easily manufactured.

(2) As illustrated in FIG. 7, the inserting direction (see the arrow A) in which the cable connector 689 is inserted into the first connector 601 is the same as the above-described normal direction (Z-axis direction).

With this configuration, the worker can insert the cable connector 689 into the first connector 601 from above the charger 100. That is, the worker can easily insert the cable connector 689 into the first connector 601.

Note that in the present disclosure, the wording that one direction (hereinafter, also referred to as the “first direction”) and another direction (hereinafter, also referred to as the “second direction”) are the same may mean that these directions are completely the same and substantially the same. The wording of “substantially the same” may mean that the first direction and the second direction are allowed to be different from each other as long as the present embodiment provides the effect in relation to the first direction and the second direction. For example, the wording that the inserting direction (see the arrow A) and the normal direction (Z-axis direction) are the substantially the same means that the inserting direction and the normal direction are allowed to be different from each other as long as the present embodiment provides the effect that “the worker easily insert the cable connector 689 into the first connector 601”.

(3) As illustrated in FIG. 1, in the state in which the charger 100 is mounted on the vehicle 10, the above-described normal direction is the same as the height direction (Z-axis direction) of the vehicle 10.

As described above, the charger 100 is mounted in the engine compartment 10A in which the other components are also mounted. In the conventional charger, the worker needs to insert a cable connector into the connector disposed in the side surface of the charger. In this case, it is troublesome to insert the cable connector into the connector because of interference with the other components. In contrast, in the configuration of the present disclosure, the worker can insert the cable connector 689 into the first connector 601 from above the charger 100. That is, the worker can easily insert the cable connector 689 into the first connector 601.

(4) As illustrated in FIG. 7B, the inserting direction (arrow A) is different from the extending direction (arrow B) of the cables 160.

With this configuration, in a state in which the cable connector 689 is inserted through the first connector 601, even when the cables 160 are pulled, the cable connector 689 is prevented from being unintentionally pulled out of the first connector 601.

Furthermore, as illustrated at the point R in FIG. 7B, the angle between the inserting direction (arrow A) and the extending direction (arrow B) is 90 degrees.

With this configuration, in the state in which the cable connector 689 is inserted through the first connector 601, even when the cables 160 are pulled, the cable connector 689 is prevented from being unintentionally pulled out of the first connector 601.

Note that in the present disclosure, the wording that “the angle between the inserting direction and the extending direction is 90 degrees” may mean that the angle is not only 90 degrees but also an angle within a range (for example, 80 degrees or greater and 100 degrees or less) other than 90 degrees. For example, the angle between the inserting direction and the extending direction may be the angle within the range other than 90 degrees as long as the present disclosure provides the effect that the cable connector 689 is prevented from being unintentionally pulled out of the first connector 601.

(5) As illustrated in FIG. 7A, when the charger 100 is viewed in the normal direction, the cables 160 overlap at least a part of the through hole 612C.

With this configuration, in a state in which a power may be supplied from the charging station 14 through the cables 160, the charger 100 of the present disclosure may have a fail-safe structure in which the worker or the others cannot access the fixing members 661 (first busbar 631 to third busbar 633). In other words, the worker or the others needs to remove the cables 160 from the charger 100 in order to access the fixing members 661. Thus, this configuration prevents the worker or the others from inadvertently coming in contact with the fixing members 661 (first busbar 631 to third busbar 633).

(6) As illustrated in FIG. 5, the connector terminal 635 includes the connector terminal main body 640 and the second busbar 632.

With this configuration, since the connector terminal 635 includes the connector terminal main body 640 and the second busbar 632, the connector terminal 635 may be manufactured individually for each component.

(7) As illustrated in FIG. 5, the second terminal base 642 is fixed to the cover 611.

With this configuration, even when the second busbar 632 is long, the second busbar 632 may be stably held on a cover side.

(8) The pair of the cables 160 is fixed with the fixing base (clamp) 162.

With this configuration, for example, even when a force in the extending direction (see the arrow B) of the cables 160 is applied to the cables 160, an effect of this force on the first connector 601 is reduced.

(9) In the charger 100, as described using FIG. 8, the second power switching assembly 302 switches between the state in which the DC voltage supplied to the first connector 601 is applied to the first busbar 631 and the state in which the AC voltage supplied to the first connector 601 is applied to the third busbar 633. The first busbar 631 is the busbar through which the DC voltage supplied to the first connector 601 is supplied to the supply circuit 190. In addition, the third busbar 633 is the busbar through which the AC voltage supplied to the first connector 601 is supplied to the converting circuit 180.

With this configuration, even when the power from the charging station 14 is any of the AC power or DC power, the first connector 601 as one charging port is sufficient for the AC charging and the DC charging, and a wiring from the charging port to the charger 100 may also be shortened.

(10) When the DC power is supplied to the first connector 601, the voltage that is greater than 0 V and 1000 V or less is supplied to the first connector 601, and when the AC power is supplied to the first connector 601, the voltage that is greater than 0 Vrms and 293 Vrms or less is supplied to the first connector 601.

With this configuration, even when the above-described voltage is supplied to the first connector 601, the battery 106 is properly charged.

### [Modification]

In the above-described connector terminal 635, the connector terminal main body 640 and the second busbar 632 are separate members. However, the connector terminal main body 640 and the second busbar 632 may be formed integrally with each other.

### [Supplementary notes]

(Item 1) A charger of the present disclosure is mounted on a vehicle. The charger includes a connector into which a cable connector of a cable through which a voltage is supplied from a charging equipment outside the vehicle is inserted, a supply circuit that supplies, to a battery of the vehicle, a power supplied to the connector, a connector terminal electrically connected to the connector, a first busbar through which the voltage is supplied to the supply circuit, a housing having an opening, and a cover covering the opening. The cover forms an accommodating space together with the housing by closing the opening. The accommodating space accommodates the supply circuit, the first busbar, and the connector terminal, and the cover has a first surface facing the accommodating space, a second surface on an opposite side of the first surface, and a through hole. The connector is fixed to the second surface. The first busbar and the connector terminal are fixed and connected to each other with a fixing member. The fixing member is disposed in the through hole as viewed in a normal direction to the second surface.

With this configuration, in a manufacturing step of the charger, a worker passes the fixing member through the through hole, and fixes and connects the first busbar and the connector terminal to each other. Accordingly, it is possible to manufacture the charger in which the connector is disposed in the second surface of the cover.

(Item 2) In the charger according to item 1, an inserting direction in which the cable connector is inserted into the connector is the same as the normal direction.

With this configuration, the worker can insert the cable connector into the connector from above the charger.

(Item 3) In the charger according to item 2, in a state in which the charger is mounted on the vehicle, the normal direction is the same as a height direction of the vehicle.

The charger is mounted in an engine compartment in which other components are also mounted. In a conventional charger, the worker needs to insert a cable connector into a connector disposed in a side surface of the charger. In this case, it is troublesome to insert the cable connector into the connector because of interference with the other components. In contrast, with the configuration of the present disclosure, the worker can insert the cable connector into the connector from above the charger. As a result, inserting the cable connector into the connector is made to be less troublesome.

(Item 4) In the charger according to item 2 or 3, the inserting direction is different from a direction in which the cable extends.

With this configuration, in a state in which the cable connector is inserted through the connector, even when the cable is pulled, the cable connector is prevented from being unintentionally pulled out of the connector.

(Item 5) In the charger according to any one of items 1 to 4, as the charger is viewed in the normal direction, the cable overlaps at least a part of the through hole.

With this configuration, in a state in which a power may be supplied through the cable, the charger of the present disclosure may have a fail-safe structure in which the worker or the others cannot access the fixing member.

(Item 6) In the charger according to any one of items 1 to 5, the connector terminal further includes a second busbar. The charger includes a terminal base to which the second busbar is fixed. The accommodating space further accommodates the second busbar. The first busbar and the second busbar are fixed and connected with the fixing member.

With this configuration, the connector terminal includes the second busbar and the other component, so that the connector terminal may be manufactured individually for each component.

(Item 7) In the charger according to item 6, the terminal base is fixed to the cover.

With this configuration, for example, even when the second busbar is long, the second busbar may be stably held by the cover.

(Item 8) In the charger according to any one of items 1 to 7, the cable is fixed with a fixing base.

With this configuration, even when a force in the extending direction of the cable is applied to the cable, an effect of this force on the connector is reduced.

(Item 9) In the charger according to any one of items 1 to 8, the DC voltage or the AC voltage is supplied from the charging equipment to the connector. The DC voltage supplied to the connector is supplied to the supply circuit through the first busbar. The supply circuit supplies, to the battery, the DC voltage supplied through the first busbar. The charger further includes a converting circuit that converts the AC voltage to a DC voltage, a third busbar through which the AC voltage supplied to the connector is supplied to the converting circuit, and a switching circuit that switches between a state in which the DC voltage supplied to the connector is applied to the first busbar and a state in which the AC voltage supplied to the connector is applied to the third busbar. The accommodating space further accommodates the third busbar. The first busbar and the third busbar are fixed and connected to each other with the fixing member.

With this configuration, even when the power from the charging equipment is any of the AC power or DC power, one connector as the charging port is sufficient for the AC charging and the DC charging, and a wiring from the charging port of the vehicle to the charger may also be shortened.

(Item 10) In the charger according to any one of items 1 to 9, when the DC power is supplied to the connector, the voltage that is greater than 0 V and 1000 V or less is supplied to the connector, and when the AC power is supplied to the connector, the voltage that is greater than 0 Vrms and 293 Vrms or less is supplied to the connector.

With this configuration, even when the above-described voltage is supplied to the connector, the battery is properly charged.

(Item 11) A manufacturing method of the present disclosure is a method of manufacturing a charger mounted on a vehicle. The manufacturing method includes preparing a cover unit and preparing a housing unit. The cover unit has a cover having a first surface, a second surface on an opposite side of the first surface, and a through hole; a connector into which a cable connector of a cable to which a voltage is supplied from a charging equipment outside the vehicle is inserted, the connector being fixed to the second surface; and a connector terminal electrically connected to the connector. The housing unit has a supply circuit that supplies a power supplied to the connector to a battery of the vehicle; a busbar through which the voltage is supplied to the supply circuit; and a housing having an opening. The manufacturing method further includes positioning the cover unit on the housing unit so that the first surface faces the housing unit and the cover covers the opening. The cover unit is positioned on the housing unit to form an accommodating space together with the housing unit. The accommodating space accommodates the supply circuit, the busbar, and the connector terminal. The manufacturing method further includes passing a fixing member through the through hole and fixing and connecting the connector terminal and the busbar to each other with the fixing member.

The embodiments disclosed herein are examples in all respects, and should not be considered restrictive. The scope of the present disclosure shall be defined by not the above-described embodiments but the claims, and is intended to include embodiments equivalent to the scope of the claims and all modifications within the scope.

What is claimed is:

1. A charger mounted on a vehicle, the charger comprising:
a connector into which a cable connector of a cable through which a voltage is supplied from a charging equipment outside the vehicle is inserted;
a supply circuit that supplies, to a battery of the vehicle, a power supplied to the connector;
a connector terminal electrically connected to the connector;
a first busbar through which the voltage is supplied to the supply circuit;
a housing having an opening; and
a cover covering the opening,
the cover forming an accommodating space together with the housing by closing the opening, and
the accommodating space accommodating the supply circuit, the first busbar, and the connector terminal, wherein
the cover has:
a first surface facing the accommodating space;
a second surface on an opposite side of the first surface; and
a through hole,
the connector is fixed to the second surface,
the first busbar and the connector terminal are fixed and connected to each other with a fixing member, and
the fixing member is disposed in the through hole as viewed in a normal direction to the second surface.

2. The charger according to claim 1, wherein
an inserting direction in which the cable connector is inserted into the connector is the same as the normal direction.

3. The charger according to claim 2, wherein
in a state in which the charger is mounted on the vehicle, the normal direction is the same as a height direction of the vehicle.

4. The charger according to claim 2, wherein
the inserting direction is different from a direction in which the cable extends.

5. The charger according to claim 1, wherein
as the charger is viewed in the normal direction, the cable overlaps at least a part of the through hole.

6. The charger according to claim 1, wherein
the connector terminal further includes a second busbar,
the charger includes a terminal base to which the second busbar is fixed,
the accommodating space further accommodates the second busbar, and
the first busbar and the second busbar are fixed and connected to each other with the fixing member.

7. The charger according to claim 6, wherein
the terminal base is fixed to the cover.

8. The charger according to claim 1, wherein
the cable is fixed with a fixing base.

9. The charger according to claim 1, wherein
the DC voltage or the AC voltage is supplied from the charging equipment to the connector,
the DC voltage supplied to the connector is supplied to the supply circuit through the first busbar,
the supply circuit supplies, to the battery, the DC voltage supplied through the first busbar,
the charger further includes:
a converting circuit that converts the AC voltage to a DC voltage;
a third busbar through which the AC voltage supplied to the connector is supplied to the converting circuit; and
a switching circuit that switches between a state in which the DC voltage supplied to the connector is applied to the first busbar and a state in which the AC voltage supplied to the connector is applied to the third busbar;
the accommodating space further accommodates the third busbar, and
the first busbar and the third busbar are fixed and connected to each other with the fixing member.

10. The charger according to claim 1, wherein
when a DC power is supplied to the connector, the voltage that is greater than 0 V and 1000 V or less is supplied to the connector, and
when an AC power is supplied to the connector, the voltage that is greater than 0 Vrms and 293 Vrms or less is supplied to the connector.

11. A method of manufacturing a charger mounted on a vehicle, the method comprising:
preparing a cover unit; and
preparing a housing unit,
the cover unit having:
a cover having a first surface, a second surface on an opposite side of the first surface, and a through hole;
a connector into which a cable connector of a cable to which a voltage is supplied from a charging equipment outside the vehicle is inserted, the connector being fixed to the second surface; and
a connector terminal electrically connected to the connector,
the housing unit having:
a supply circuit that supplies a power supplied to the connector to a battery of the vehicle;
a busbar through which the voltage is supplied to the supply circuit; and
a housing having an opening,
the method further comprising positioning the cover unit on the housing unit so that the first surface faces the housing unit and the cover covers the opening,
the cover unit, together with the housing unit, forming an accommodating space by being positioned on the housing unit, and
the accommodating space accommodating the supply circuit, the busbar, and the connector terminal, wherein
the method further includes:
passing a fixing member through the through hole; and
fixing and connecting the connector terminal and the busbar to each other with the fixing member.
